(19) United States
(12) Patent Application Publication
(10) Pub. No.: US 2023/0295537 A1
(43) Pub. Date: Sep. 21, 2023

(54) MICROELECTRONIC DEVICE CLEANING COMPOSITION

(71) Applicant: ENTEGRIS, INC., Billerica, MA (US)

(72) Inventors: Jun Liu, Newtown, CT (US); Chao-Yu Wang, Zhubei City (TW); Daniela White, Ridgefield, CT (US); Michael L. White, Ridgefield, CT (US)

(21) Appl. No.: 18/117,175

(22) Filed: Mar. 3, 2023

Related U.S. Application Data
(60) Provisional application No. 63/319,782, filed on Mar. 15, 2022.

(51) Int. Cl. C11D 7/32; C11D 11/00; C11D 7/34; C11D 7/50; H01L 21/02

(52) U.S. Cl. CPC C11D 7/3218; C11D 11/0047; C11D 7/34; C11D 7/3272; C11D 7/5022; H01L 21/02074

(57) ABSTRACT

The invention provides compositions useful in post-CMP cleaning operations, particularly those substrates which contain exposed copper surfaces. The compositions of the invention provide excellent cleaning of such substrates while showing fewer defects from silica and organic materials present at the surface of the substrate. Also provided is a method for cleaning a microelectronic device substrate using such compositions and a kit comprising, in two or more containers, the components of the compositions.

### TECHNICAL FIELD

The invention relates generally to aqueous compositions for cleaning the surface of a microelectronic device substrate.

### BACKGROUND

Microelectronic device substrates are used for preparing integrated circuit devices. The microelectronic device substrate includes a base, such as a silicon wafer having a highly planar surface. Onto the planar surface of the base, by way of many multiples of selective placement and removal steps, regions of electronically-functional features are added. The features are made by selectively adding and removing electronically-functional materials that exhibit insulative, conductive, or semi-conductive properties. These electronically-functional materials are placed as desired by use of processing materials that include photoresist, chemical etchant, and slurries that contain abrasive particles and chemical materials that aid in processing the surface.

One feature of integrated circuits is an array of conductive “interconnects,” which are also referred to as “lines” and “vias.” As part of an integrated circuit, conductive interconnects function to conduct electric current among and between various other electronic features. Each interconnect is in the form of a line or thin film of conductive material that extends within and is defined (in shape and size) by openings formed in an insulative material, such as a dielectric material. The dielectric material acts as an insulator between the very-closely spaced interconnect structures, and between the interconnect structures and other electronic features of the integrated circuit.

The types of materials used to produce the interconnect and the dielectric structures must be selected to properly function as part of an integrated circuit that performs at high efficiency and high reliability. For example, the conductive material of an interconnect should be of a type that does not migrate (e.g., diffuse) excessively into an adjacent dielectric material over time and during use in the presence of a voltage between the materials; such migration of interconnect material into an adjacent dielectric material is often referred to as “electromigration.” At the same time, the combined interconnect and dielectric material structure must have sufficient integrity, including at an interface between these materials, to result in a low level of defects and a high level of performance reliability. For example, a strong bond must exist at the interface to prevent separation of the dielectric material from the interconnect material during use.

Interconnects have in the past been commonly made of aluminum or tungsten, and more recently are made of copper. Copper has an advantageously high conductivity relative to aluminum and tungsten. In addition, copper-based interconnects offer better resistance to electromigration as compared to aluminum, thereby improving the reliability of the integrated circuit over time. Still, copper ions can tend to diffuse into silicon dioxide (SiO₂) under sufficient electrical bias, and adhesion of copper to silicon dioxide and to other dielectric materials can be poor.

To prevent these negative interactions of copper with a dielectric material, recent integrated circuit structures have been designed to include a barrier layer between a copper interconnect structure and an adjacent dielectric material. Example barrier layers may be conductive materials or non-conductive materials, examples including tantalum (Ta), tantalum nitride (TaNₓ), tungsten (W), titanium (Ti), titanium nitride (TiN), ruthenium (Ru), cobalt (Co), molybdenum (Mo), rhenium (Rh), and alloys thereof.

Processes of placing the various features of microelectronic devices onto a substrate include selectively placing insulative materials, semiconducting materials, and metal materials onto a substrate surface. Selective placement and removal of these materials may involve the use of process compositions such as photoresist, etchant, CMP slurries that contain abrasive and chemical materials, and plasma, among others, in steps such as photoresist coating, etching (e.g., wet etching, plasma etching), chemical-mechanical processing (a.k.a., chemical-mechanical polishing, chemical-mechanical planarization, or simply “CMP”), and ashing (“plasma ashing”).

Chemical-mechanical processing is a process by which very small amounts (thicknesses) of material are precisely removed from a surface of a microelectronic device substrate to polish (or “planarize”) the surface in preparation for a subsequent layer of material to be applied onto the processed surface. Chemical-mechanical processing involves highly precise mechanical abrasion of a surface, coupled with controlled interactions of chemical materials, such as oxidation, reduction, or chelation of a material that is present at or removed from the surface. Often, one type of material at the substrate surface is preferentially removed with high selectivity, in comparison to a reduced degree of removal of one or more other materials that are also present at the surface.

A CMP process involves applying a “slurry” to the surface along with contacting the surface with a moving CMP pad. The “slurry” is a liquid composition that contains microabrasive particles that provide mechanical abrasion of the surface, along with chemical materials that interact chemically with materials of the surface to facilitate selective removal of certain material from the surface and often to inhibit removal of another surface material. The slurry is applied to the surface while the CMP pad contacts the surface with the desired amount of pressure and motion to facilitate the abrasive and chemical removal of select materials from the surface. The combination of the mechanical action of the pad and abrasive particles moving against the surface, along with the action of the chemical ingredients, achieves desired removal, planarization, and polishing of the surface with desired low levels of defects and residue. The CMP process should produce a highly planar, low-defect, low-residue surface to which a subsequent layer of a microelectronic device can be applied.

After a processing step (e.g., chemical-mechanic processing, etching, ashing, etc.), at least some amount of residue will be present at a surface of a substrate. Residue may include abrasive particles from a CMP slurry or other processing material; active chemical ingredients that are part of a CMP slurry (e.g., oxidizer, catalyst, inhibitor) or other processing composition; a reaction product or by-product of a processing material or ingredient thereof; a chemical etchant; photoresist polymer or other solid processing ingredient; etc. Any such residue must be removed by cleaning the surface before performing a subsequent step of a microelectronic device fabrication process, to avoid defects or other potential sources of reduced device performance or reliability.

Certain methods and equipment commonly used for cleaning a surface of a microelectronic substrate, e.g., after an etching step, after a CMP step, or after another step used in fabricating a multi-layer microelectronic device, include those that involve a flow of cleaning solution over the surface in combination with megasonics, jetting, or brushing to remove residue and contaminants. Typical cleaning solutions are alkaline solutions, e.g., containing a suitable hydroxide compound along with other chemical materials that together remove residue from the surface by chemically interacting with the residue. The cleaning solution should be effective to remove a high percentage of residue from a surface, but also must be safe with respect to functional features of the substrate. A cleaning solution must not cause damage to those features. For example, a cleaning solution should not cause corrosion (i.e., oxidation) of a metal feature of a substrate, e.g., should not oxidize copper metal features of a substrate that may be present as interconnect or barrier features.

New, useful, and improved cleaning compositions and specific ingredients are continually sought, especially for use with new microelectronic device structures such as those that may now include exposed surfaces of copper.

### SUMMARY

In summary, the invention provides compositions useful in post-CMP cleaning operations, particularly those substrates which contain exposed copper surfaces. The compositions of the invention provide excellent cleaning of such substrates while showing fewer defects from silica and organic materials present at the surface of the substrate. Also provided is a method for cleaning a microelectronic device substrate using such compositions and a kit comprising, in two or more containers, the components of the compositions.

### DETAILED DESCRIPTION

As used in this specification and the appended claims, the singular forms “a”, “an”, and “the” include plural referents unless the content clearly dictates otherwise. As used in this specification and the appended claims, the term “or” is generally employed in its sense including “and/or” unless the content clearly dictates otherwise.

The term “about” generally refers to a range of numbers that is considered equivalent to the recited value (e.g., having the same function or result). In many instances, the term “about” may include numbers that are rounded to the nearest significant figure.

Numerical ranges expressed using endpoints include all numbers subsumed within that range (e.g., 1 to 5 includes 1, 1.5, 2, 2.75, 3, 3.80, 4 and 5).

In a first aspect, the invention provides a composition comprising:
a. water;
b. a cleaning additive chosen from cysteine; cystine; 2-aminothiophenol; 2-thiazoline-2-thiol; 1,3,4-thiadiazole-2-,5-dithiol; 1,3,4-thiadiazole-2-methyl-5-thiol; and ethyldithiocarbamate; and salts thereof;
c. a chelating agent chosen from monoethanolamine; ethanolamine; hydroxyethylidene diphosphonic acid; 2-amino-2-(hydroxymethyl)-1,3-propanediol; diglycolamine; diisopropanolamine; isopropanolamine; nitrilo tris-(methylenephosphonic acid); diethylene triamine pentamethylene phosphonic acid; phosphoric acid; and triethanolamine;
d. a reducing agent chosen from diethyl hydroxylamine; ascorbic acid, hypophosphorous acid; and sulfurous acid;
e. a corrosion inhibitor chosen from dicyandiamide; guanylurea; and glycocyamine; and
f. a pH adjustor.

In one embodiment, the composition will be comprised of about 60 to 90 weight percent water, about 0.01 to about 10 weight percent of a cleaning agent, about 0.005 to about 10 weight percent of a chelating additive, about 0.01 to about 5 weight percent of a reducing agent chosen from diethyl hydroxylamine; ascorbic acid, hypophosphorous acid; and sulfurous acid; and about 0.01 to about 3 weight percent of a corrosion inhibitor chosen from dicyandiamide; guanylurea; and glycocyamine.

As used herein, unless otherwise specified, a composition or ingredient of a composition that is described as “consisting essentially of” one or more specified items refers to a composition or ingredient that is made up of only those specified items with not more than an insubstantial amount of other (additional) materials, e.g., contains only the specified items and not more than 5, 3, 2, 1, 0.5, 0.1, 0.05, or 0.01 weight percent additional ingredients based on the total weight of the composition or the ingredient. As used herein, a composition or ingredient of a composition that is described as “consisting of” one or more specified items refers to a composition or ingredient that is made up of only those specified items. In certain embodiments, the compositions consist of or consist essentially of components a. through f. above.

In certain embodiments, the pH of the composition will be about 8 to about 14, with the pH adjustors recited herein utilized in sufficient quantities to achieve such pH ranges.

In the compositions of the invention, various pH adjustors may be utilized. Examples include bases such as potassium hydroxide, ammonium hydroxide (i.e., aqueous ammonia), and a tetraalkylammonium hydroxide compound having the formula NR⁴R⁵R⁶R₇OH, wherein R⁴, R⁵, R⁶ and R⁷ may be the same as or different from one another and are chosen from hydrogen, straight-chain or branched C₁-C₆ alkyl (e.g., methyl, ethyl, propyl, butyl, pentyl, and hexyl) groups, C₁-C₆ hydroxyalkyl (e.g., hydroxymethyl, hydroxyethyl, hydroxypropyl, hydroxybutyl, hydroxypentyl, and hydroxyhexyl) groups, and substituted or unsubstituted C₆-C₁₀ aryl groups (e.g., benzyl groups). Exemplary tetraalkylammonium hydroxides include tetramethylammonium hydroxide (TMAH), tetraethylammonium hydroxide (TEAH), tetrapropylammonium hydroxide (TPAH), tetrabutylammonium hydroxide (TBAH), tributylmethylammonium hydroxide (TBMAH), benzyltrimethylammonium hydroxide (BTMAH), choline hydroxide, ethyltrimethylammonium hydroxide, tris(2-hydroxyethyl)methyl ammonium hydroxide, diethyldimethylammonium hydroxide, and combinations thereof. Alternatively or in addition, the pH adjusting agent may be a quaternary base having the formula (PR⁸R⁹R¹⁰R¹¹)OH, wherein R⁸, R⁹, R¹⁰, and R¹¹ may be the same as or different from one another and are chosen from hydrogen, straight-chain C₁-C₆ alkyl (e.g., methyl, ethyl, propyl, butyl, pentyl, and hexyl) groups, branched C₁-C₆ alkyl groups, C₁-C₆ hydroxyalkyl (e.g., hydroxymethyl, hydroxyethyl, hydroxypropyl, hydroxybutyl, hydroxypentyl, and hydroxyhexyl) groups, substituted C₆-C₁₀ aryl groups, unsubstituted C₆-C₁₀ aryl groups (e.g., benzyl groups), and any combination thereof, such as tetrabutylphosphonium hydroxide (TBPH), tetramethylphosphonium hydroxide, tetraethylphosphonium hydroxide, tetrapropylphosphonium hydroxide, benzyltriphenylphosphonium hydroxide, methyl triphenylphosphonium hydroxide, ethyl triphenylphosphonium hydroxide, N-propyl triphenylphosphonium hydroxide.

In certain embodiments, the composition further comprises one or more additional chelating or complexing agents. In this regard, such additional chelating or complexing agents include amino acids such as glycine, alanine, serine, arginine, histidine, lysine, glutamic acid, serine, threonine, and proline. Others include phosphonates (e.g., 1-hydroxyethylidene-1,1-diphosphonic acid (HEDP), 1,5,9-triazacyclododecane-N,N′,N″-tris(methylenephosphonic acid) (DOTRP), 1,4,7,10-tetraazacyclododecane-N,N′,N″,N′″-tetrakis(methylenep-hosphonic acid) (DOTP), nitrilotris(methylene)triphosphonic acid, diethylenetriaminepentakis(methylenephosphonic acid) (DETAP), aminotri(methylenephosphonic acid), bis(hexamethylene)triamine pentamethylene phosphonic acid, 1,4,7-triazacyclononane-N,N′,N″-tris(methylenephosphonic acid (NOTP), hydroxyethyldiphosphonate, nitrilotris(methylene)phosphonic acid, 2-phosphono-butane-1,2,3,4-tetracarboxylic acid, carboxyethyl phosphonic acid, aminoethyl phosphonic acid, glyphosate, ethylene diamine tetra(methylenephosphonic acid) phenylphosphonic acid, salts thereof, and derivatives thereof) and/or carboxylic acids (e.g., oxalic acid, succinic acid, maleic acid, malic acid, malonic acid, adipic acid, phthalic acid, citric acid, sodium citrate, potassium citrate, ammonium citrate, tricarballylic acid, dimethylolpropionic acid, trimethylolpropionic acid, tartaric acid, glucuronic acid, 2-carboxypyridine) and/or sulfonic acids such as 4,5-dihydroxy-1,3-benzenedisulfonic acid disodium salt. In certain embodiments such additional complexing agents are chosen from citric acid and 1-hydroxyethylidene-1,1-diphosphonic acid.

In other embodiments, the compositions further comprise one or more water-miscible solvents. Examples of water-miscible solvents include, glycols, and glycol ethers, including, but not limited to, methanol, ethanol, isopropanol, butanol, and higher alcohols (such as C₂-C₄ diols and C₂-C₄ triols), tetrahydrofurfuryl alcohol (THFA), halogenated alcohols (such as 3-chloro-1,2-propanediol, 3-chloro-1-propanethiol, 1-chloro-2-propanol, 2-chloro-1-propanol, 3-chloro-1-propanol, 3-bromo-1,2-propanediol, 1-bromo-2-propanol, 3-bromo-1-propanol, 3-iodo-1-propanol, 4-chloro-1-butanol, 2-chloroethanol), dichloromethane, chloroform, acetic acid, propionic acid, trifluoroacetic acid, tetrahydrofuran N-methylpyrrolidinone (NMP), cyclohexylpyrrolidinone, N-octylpyrrolidinone, N-phenylpyrrolidinone, methyldiethanolamine, methyl formate, dimethyl formamide (DMF), dimethylsulfoxide (DMSO), tetramethylene sulfone (sulfolane), diethyl ether, phenoxy-2-propanol (PPh), propriophenone, ethyl lactate, ethyl acetate, ethyl benzoate, acetonitrile, acetone, ethylene glycol, propylene glycol (PG), 1,3-propanediol, dioxane, butyryl lactone, butylene carbonate, ethylene carbonate, propylene carbonate, dipropylene glycol, diethylene glycol monomethyl ether, triethylene glycol monomethyl ether, diethylene glycol monoethyl ether, triethylene glycol monoethyl ether, ethylene glycol monopropyl ether, ethylene glycol monobutyl ether, diethylene glycol monobutyl ether (i.e., butyl carbitol), triethylene glycol monobutyl ether, ethylene glycol monohexyl ether, diethylene glycol monohexyl ether, ethylene glycol phenyl ether, propylene glycol methyl ether, dipropylene glycol methyl ether (DPGME), tripropylene glycol methyl ether (TPGME), dipropylene glycol dimethyl ether, dipropylene glycol ethyl ether, propylene glycol n-propyl ether, dipropylene glycol n-propyl ether (DPGPE), tripropylene glycol n-propyl ether, propylene glycol n-butyl ether, dipropylene glycol n-butyl ether, tripropylene glycol n-butyl ether, propylene glycol phenyl ether, ethylene glycol monophenyl ether, diethylene glycol monophenyl ether hexaethylene glycol monophenylether, dipropylene glycol methyl ether acetate, tetraethylene glycol dimethyl ether (TEGDE), dibasic ester, glycerine carbonate, N-formyl morpholine, triethyl phosphate, and combinations thereof.

In other embodiments, the composition further comprises one or more water-dispersible or water-soluble polymers. Such polymers, when present, include but are not limited to methacrylic acid homopolymer and copolymers with, for example, acrylamidomethylpropane sulfonic acid and maleic acid; maleic acid/vinyl ether copolymer; poly(vinylpyrrolidone)/vinyl acetate; homopolymers such as phosphonated polyethyleneglycol oligomers, poly(acrylic acid) (PAA), poly(acrylamide), poly(vinyl acetate), poly(ethylene glycol) (PEG), polypropylene glycol) (PPG), poly(styrene sulfonic acid), poly(vinyl sulfonic acid), poly(vinyl phosphonic acid), poly(vinyl phosphoric acid), poly(ethyleneimine), poly(propyleneimine), polyallylamine, polyethylene oxide (PEO), polyvinyl pyrrolidone (PVP), PPG-PEG-PPG block copolymers, PEG-PPG-PEG block copolymers, poly(vinyl alcohol), poly(hydroxyethyl)acrylate, poly(hydroxyethyl)methacrylate, hydroxyethyl cellulose, methylhydroxyethyl cellulose, hydroxypropyl cellulose, methylhydroxypropyl cellulose, xanthan gum, potassium alginate, pectin, carboxymethylcellulose, glucosamine, poly(diallyldimethylammonium) chloride, PEGylated (i.e., polyethyleneglycol-ated) methacrylate/acrylate copolymers, poly MADQuat (poly(2-methacryloxyethyltrimethylammonium chloride—CAS Number 26161-33-1) and copolymers thereof, dimethylaminomethacrylate polymers and compolymers thereof, trimethylammonium methylmethacrylate polymers and copolymers thereof, and combinations thereof. The copolymers above may be random or block copolymers. When present, the amount of polymer(s) in the composition is in a range from about 0.0001 weight % to about 5 weight %, based on the total weight of the composition.

In other embodiments, the compositions further comprise one or more surfactants. In another embodiment, the composition further comprises a nonionic surfactant. As used herein the term “surfactant” refers to an organic compound that lowers the surface tension (or interfacial tension) between two liquids or between a liquid and a solid, typically an organic amphiphilic compound that contains a hydrophobic group (e.g., a hydrocarbon (e.g., alkyl) “tail”) and a hydrophilic group. When present, these non-ionic surfactants for use in the compositions described herein include, but are not limited to, polyoxyethylene lauryl ether, dodecenylsuccinic acid monodiethanol amide, ethylenediamine tetrakis (ethoxylate-block-propoxylate) tetrol, polyethylene glycols, polypropylene glycols, polyethylene or polypropylene glycol ethers, block copolymers based on ethylene oxide and propylene oxide, polyoxypropylene sucrose ether, t-octylphenoxypolyethoxyethanol, 10-ethoxy-9,9-dimethyldecan-1-amine, Polyoxyethylene (9) nonylphenylether, branched, Polyoxyethylene (40) nonylphenylether, branched, dinonylphenyl polyoxyethylene, nonylphenol alkoxylates, polyoxyethylene sorbitol hexaoleate, polyoxyethylene sorbitol tetraoleate, polyethylene glycol sorbitan monooleate, sorbitan monooleate, alcohol alkoxylates, alkyl-polyglucoside, ethyl perfluorobutyrate, 1,1,3,3,5,5-hexamethyl-1,5-bis[2-(5-norbornen-2-yl)ethyl]trisiloxane, monomeric octadecylsilane derivatives, siloxane modified polysilazanes, silicone-polyether copolymers, and ethoxylated fluorosurfactants.

In another embodiment, the composition further comprises a biocide. Exemplary biocides include 5-chloro-2-methyl-4-isothiazolin-3-one, 2-methyl-4-isothiazolin-3-one, benzisothiazolone, 1, 2-benzisothiazol-3[2H]-one, methylisothiazolinone, methylchloroisothiazolinone, and combinations thereof.

As used herein, the term “residue” (which is inclusive of a “contaminant”) refers to any material that is a chemical or particulate material that remains present at a surface of a microelectronic device substrate after a processing step used in the fabrication of a microelectronic device, for example processing steps including plasma etching, plasma ashing (to remove photoresist from an etched wafer), chemical-mechanical processing, wet etching, etc. The residue may be any non-aqueous chemical material that is part of a processing composition used in the processing step, such as a chemical etchant, a photoresist, a CMP slurry, etc. The residue may alternately be a substance that is derived from a material of the processing composition during a processing step. Examples of these types of residues include non-aqueous, particulate or non-particulate, chemical or abrasive materials (e.g., abrasive particles, surfactant, oxidizer, corrosion inhibitor, catalyst) that remain at a surface of the substrate after processing. The residue may be originally present in a material such as a CMP slurry or an etching composition, such as a solid abrasive particle or chemical material present in a CMP abrasive slurry. Alternately, a residue may be a by-product or a reaction product (in particulate (e.g., agglomerate or precipitate) or non-particulate form that is generated during processing, e.g., a by-product or reaction product of a chemical present in a processing composition such as CMP slurry or wet etching composition, or a chemical that is present, used during, or produced during a plasma etching or a plasma ashing process.

The term “post-CMP residue” refers to residue that is present at an end of a CMP processing step, for example a particle or chemical material that is present in or derived from a CMP slurry; specific examples include abrasive particles (e.g., silica-containing or silica-based abrasive particles, metal oxide (e.g., alumina) particles, ceria or ceria-based particles and the like); chemicals that are originally present in the slurry such as an oxidizer, catalyst, surfactant, inhibitor, complexing agent, etc.; a metal, metal oxide, or metal complex that is derived from a metal material removed from the substrate surface being processed; or a reaction product or complex produced using a chemical of the slurry with another chemical of the slurry or with a chemical material derived from the substrate, such as a metal ion; pad particles; or any other material that is a product of the CMP process.

A “post-etch residue” refers to a material remaining following a gas-phase plasma etching process, e.g., back-end-of-line (“BEOL”) dual damascene processing, or wet etching processes. A post-etch residue may be organic, organometallic, organosilicic, or inorganic in nature, for example, silicon-containing material, carbon-based organic material, and etch gas residues such as oxygen and fluorine.

A “post-ash residue” refers to material remaining following oxidative or reductive plasma ashing to remove hardened photoresist and/or bottom anti-reflective coating (BARC) materials. The post-ash residue may be organic, organometallic, organosilicic, or inorganic in nature.

As noted above, the present invention relates to compositions which are useful in a cleaning method that removes residue from a surface of a microelectronic device substrate that has residue thereon. The compositions contain an aqueous carrier (i.e., water) along with a combination of non-aqueous ingredients as set forth herein. In certain embodiments, the compositions, before being used in a cleaning process, are homogeneous solutions that comprise, consist of, or consist essentially of water and dissolved non-aqueous ingredients, in the absence of any solid or suspended materials such as solid abrasive particles, agglomerates, coagulates, etc.

The compositions as described herein are useful for cleaning microelectronic devices and precursors thereof, specifically including microelectronic device substrates, meaning semiconductor wafers that include on a surface one or more microelectronic devices or precursors thereof that are in the process of being fabricated into final, completed and functional microelectronic devices.

As used herein, a microelectronic device is a device that includes electrical circuits and related structures of very small (e.g., micron-scale or smaller) dimensions formed thereon. Exemplary microelectronic devices include flat panel displays, integrated circuits, memory devices, solar panels, photovoltaics, and microelectromechanical systems (MEMS). A microelectronic device substrate is a structure such as a wafer (e.g., semiconductor wafer) that includes one or more microelectronic devices or precursors thereof, in a state of being prepared to form a final microelectronic device.

The compositions and methods described herein are useful to clean any of various forms of microelectronic devices, at any stage of processing. A high percentage of residue that is present at a substrate surface can be successfully removed from the surface by use of cleaning compositions and methods described herein, for example at least 70, 80, 85, 90, 95, or 99 percent of residue may be removed (also referred to as “cleaning efficiency”).

Methods and equipment for measuring residue at a surface of a microelectronic device substrate are well known. Cleaning efficiency may be rated based on a reduction of an amount (e.g., number) of residue particles present on a microelectronic device surface after cleaning, compared to the amount (e.g., number) of residue particles present before cleaning. For example, pre- and post-cleaning analysis may be carried out using an atomic force microscope. Residue particles on a surface may be registered as a range of pixels. A histogram (e.g., a Sigma Scan Pro) may be applied to filter the pixels in a certain intensity, e.g., 231-235, and the number of residue particles counted. The amount of residue particle removal, i.e., cleaning efficiency, may be calculated using the ratio:

### (Number of PreClean Residue Particles on a Surface-Number of PostClean Residue Particles on the Surface)/(Number of PreClean Residue Particles on the Surface).

Alternately, cleaning efficiency may be considered as a percentage of a total amount of a substrate surface that is covered by residue particulate matter before as compared to after cleaning. For example, an atomic force microscope may be programmed to perform a z-plane scan to identify topographic areas of interest above a certain height threshold, and then calculate the area of the total surface covered by the areas of interest. A reduced amount of area determined to be areas of interest, after cleaning, indicates a more efficacious cleaning composition and cleaning process.

The compositions of the invention can be prepared and then sold in the form a concentrate, which contains water at a relatively low amount, and, consequently, a relatively concentrated amount of non-aqueous ingredients. The concentrate can be prepared commercially to be sold and transported while containing the concentrated amount of non-aqueous ingredients and relatively reduced amount of water, and to be eventually diluted by a purchaser of the concentrate at a point of use. The amounts of the different non-aqueous ingredients in the concentrate are amounts that, upon dilution of the concentrate, will result in desired amounts of those non-aqueous ingredients being present in the composition as ultimately utilized.

The composition as described includes water as a liquid carrier, i.e., solute, of the non-aqueous ingredients. The water can be deionized (DIW) water. Water can be present in the composition from any source, such as by being contained in an ingredient that is combined with other ingredients to produce a composition in the form of a concentrate; or as water combined in pure form to other ingredients of a concentrate; or as water added to a concentrate by a user, e.g., at a point of use, as dilution water for the purpose of diluting the concentrate to form a use composition.

The amount of water in a composition can be a desired amount for a concentrate, or a desired amount of a use composition, which is generally a higher total amount relative to the amount of water in a concentrate. Exemplary amounts of water in a concentrate composition, not to be considered limiting, may be from about 30, 40, or 50 to about 85 or 90 weight percent, e.g., from about 60, 65, or 70 to about 80 weight percent water, based on total weight of a concentrate composition. Upon dilution, these amounts will be reduced by a factor of the dilution. Example amounts of water in a use composition may be from about 70 to about 99.9 weight percent, e.g., from about 90 or 99.55 to about 95 or 99 weight percent water based on total weight of the use composition.

The composition of the invention can be easily prepared by simple addition of the respective ingredients and mixing to homogeneous condition, such as a solution. Furthermore, a composition may be readily formulated as single-package formulations or multi-part formulations that are mixed at or before the point of use, e.g., the individual parts of the multi-part formulation may be mixed by a user either at a processing tool (cleaning apparatus) or in a storage tank upstream of the processing tool.

Accordingly, another aspect of the invention relates to a kit including, in two or more containers, various components of the composition as set forth herein, suitable for storing and shipping the compositions and may include, for example, NOWPak® containers (Entegris, Inc., Billerica, MA, USA). Thus, in a third aspect, the invention provides a kit, comprising in two or more containers, two or more of
a. water;
b. a cleaning additive chosen from cysteine; cystine; 2-aminothiophenol; 2-thiazoline-2-thiol; 1,3,4-thiadiazole-2-,5-dithiol; 1,3,4-thiadiazole-2-methyl-5-thiol; and ethyldithiocarbamate; and salts thereof;
c. a chelating agent chosen from monoethanolamine; ethanolamine; hydroxyethylidene diphosphonic acid; 2-amino-2-(hydroxymethyl)-1,3-propanediol; diglycolamine; diisopropanolamine; isopropanolamine; nitrilo tris-(methylenephosphonic acid); diethylene triamine pentamethylene phosphonic acid; phosphoric acid; and triethanolamine;
d. a reducing agent chosen from diethyl hydroxylamine; ascorbic acid, hypophosphorous acid; and sulfurous acid;
e. a corrosion inhibitor chosen from dicyandiamide; guanylurea; and glycocyamine; and
f. a pH adjustor.

The compositions and method of the invention are effective to remove a substantial amount of residue from the surface, of an amount that is initially present at the surface before the cleaning step. In one embodiment, the cleaning composition can be effective, in a cleaning step, to remove at least 85 percent of residue present on a surface of the substrate prior to residue removal by a cleaning step, or at least 90 of residue, or at least 95 percent of residue, or at least 99 percent of residue initially present before the cleaning step.

In a cleaning step, such as a post-CMP residue cleaning step, a cleaning composition may be used with any of a variety of known, conventional, commercially available cleaning tools such as megasonics and brush scrubbing, including, but not limited to, Verteq single wafer megasonic Goldfinger, OnTrak systems DDS (double-sided scrubbers), SEZ or other single wafer spray rinse, Applied Materials Mirra-Mesa™/Reflexion™/Reflexion LK™, and Megasonic batch wet bench systems, and Ebara Technologies, Inc. products such as 300 mm models (FREX300S2 and FREX300X3SC) and the 200 mm CMP system (FREX200M).

Conditions and timing of a cleaning step can be as desired, and may vary depending on the type of substrate and residue. In use of a composition for cleaning post-CMP residue, post-etch residue, post-ash residue or contaminants from a microelectronic device substrate having same thereon, the cleaning composition may be contacted with the substrate surface for a time of from about 1 second to about 20 minutes, e.g., from about 5 seconds to 10 minutes, or from about 15 seconds to about 5 minutes, at temperature in a range of from about 20° C. to about 90° C., or about 20° C. to about 50° C. Such contacting times and temperatures are illustrative, and any other suitable time and temperature conditions may be useful if efficacious to at least partially clean an initial amount of residue from a surface.

Following the desired level of cleaning of a device substrate surface, the cleaning compositions used in a cleaning step may be readily removed from the device surface, as may be desired and efficacious in a given end use application. For example, removal may be performed by use of a rinse solution that includes deionized water. Thereafter, the device may be processed as desired, such as by being dried (e.g., using nitrogen or a spin-dry cycle), followed by subsequent processing of the cleaned and dried device surface.

In other more general or specific methods, a microelectronic device substrate may first be subjected to processing step that includes by any one or more of CMP processing, plasma etching, wet etching, plasma ashing, or the like, followed by a cleaning step that includes cleaning the substrate surface with the composition of the present invention. At the end of the first processing step, residue (e.g., post-etch residue, post-CMP residue, post ash residue, etc.) will be present at a surface of the substrate. The cleaning step, using a cleaning composition as described, will be effective to clean a substantial amount of the residue from the microelectronic device surface.

Thus, in a third aspect, the invention provides a method for removing residues on a microelectronic device substrate, the method comprising:
A. contacting the surface of the microelectronic device substrate with a composition comprising:
   a. water;
   b. a cleaning additive chosen from cysteine; cystine; 2-aminothiophenol; 2-thiazoline-2-thiol; 1,3,4-thiadiazole-2-,5-dithiol; 1,3,4-thiadiazole-2-methyl-5-thiol; ethyldithiocarbamate; and salts thereof;
   c. a chelating agent chosen from monoethanolamine; ethanolamine; hydroxyethylidene diphosphonic acid; 2-amino-2-(hydroxymethyl)-1,3-propanediol; diglycolamine; diisopropanolamine; isopropanolamine; nitrilo tris-(methylenephosphonic acid); diethylene triamine pentamethylene phosphonic acid; phosphoric acid; and triethanolamine;
   d. a reducing agent chosen from diethyl hydroxylamine, ascorbic acid, hypophosphorous acid, and sulfurous acid;
   e. a corrosion inhibitor chosen from dicyandiamide, guanylurea and glycocyamine; and
   f. a pH adjustor; and
B. at least partially removing the residues from the microelectronic device substrate.

This invention can be further illustrated by the following examples of preferred embodiments thereof, although it will be understood that these examples are included merely for purposes of illustration and are not intended to limit the scope of the invention unless otherwise specifically indicated.

### EXAMPLES—CONCENTRATED FORMULATIONS

| Example | Choline | | L- | | | Dowanol | |
|---|---|---|---|---|---|---|---|
| No. | Hydroxide | Monoethanolamine | cysteine | ** | *** | PnB | TEGMBE |
| Comparative | 0.1175 | 4.5 | 0.05 | | | | |
| Example* | | | | | | | |
| Example 1 | 28 | 5 | 0.12 | 3.6 | 0.8 | | |
| Example 2 | 28 | 5 | 0.12 | | 0.8 | | 2.388 |
| Example 3 | 28 | 5 | 0.12 | | 0.8 | | |
| Example 4 | 28 | 5 | 0.12 | | 0.8 | 1.533 | |
| Example 5 | 28 | 5 | 0.12 | 3.6 | 0.8 | 1.533 | |

*Recommended dilution = 60X; for all Examples, recommended dilution = 240X
**DEHA = CAS No. 3710-84-7
***Dicyandiamide, CAS No. 461-58-5

### EXPERIMENTAL RESULTS

In these experiments, 300 mm copper blanket wafers were polished and cleaned in a Reflexion® LK CMP tool using applicable consumables, such as slurries, pads, and brushes. An SP-3 defect inspection tool was used to detect defect counts with 80 nm defect size. EDR-7380 defect review tool (KLAT), including microscope, SEM, and EDX, was then employed to categorize defects in terms of organics, silica, etc. The data in Table 1 below shows the improved cleaning compositions of Examples 1-4 over the comparative example; These PCMP cleaners resulted in significantly reduced amount of organic residues on copper blanket wafers. The silica particle cleaning performance is comparable among those tested solutions.

TABLE 1

| | | | Å/minute at recommended | |
|---|---|---|---|---|
| | | | dilution | |
| | Defects | Defects | Cu etch | Co Etch |
| | (organics) | (SiO₂) | rate | Rate |
| Comparative | 142 | 2 | 1.35 | 0.6 |
| Example | | | | |
| Example 1 | 1 | 3 | 0.63 | 0.22 |
| Example 2 | 1 | 10 | 0.61 | 0.17 |
| Example 3 | 1 | 2 | 0.62 | 0.28 |
| Example 4 | 1 | 1 | 0.68 | 0.42 |
| Example 5 | 1 | 4 | 0.65 | 0.2 |

A comparison of three corrosion inhibitors (dicyandiamide, guanylurea, and glycocyamine) added into 4.5% MEA (CAS No. 141-43-5) showed reduced Cu etch rate, while showing negligible impact on Co etch rate.

TABLE 2

| | Cu Etch | Co Etch |
|---|---|---|
| Formulation | Rate | Rate |
| control (4.5% MEA) | 3.68 | 0.21 |
| control + 0.52% dicyandiamide | 1.10 | 0.29 |
| (CAS# 461-58-5) | | |
| control + 1.87% guanylurea sulfate | 2.74 | 0.25 |
| (CAS# 591-01-5) | | |
| control + 0.73% glycocyamine | 3.15 | 0.26 |
| (CAS# 352-97-6) | | |

Alternative chelating agents and reducing agents tested in the below control formulation resulted in a reduction in Co etch rate.

TABLE 3

| Formulation | Co Etch Rate |
|---|---|
| Control (6.87% KOH, 2.5% MEA, 0.8% HEDP, | 1.91 |
| 0.8% PVP) PVP CAS No. 9003-39-8 | |
| Control − 2.5% MEA + 4.33% DGA (CAS No. 929-06-6) | 1.41 |
| Control − 2.5% MEA + 4.96% TRIZMA | 1.51 |
| (CAS No. 77-86-1) | |
| Control − 2.5% MEA + 5.47%% DIPA | 1.32 |
| (CAS No. 110-97-4) | |
| Control + 1.8% DEHA (CAS No. 3710-84-7) | 1.69 |
| Control + 0.67% hypophosphorous acid | 1.37 |
| (CAS No. 6303-21-5) | |
| Control + 3.5% ascorbic acid (CAS No. 50-81-7) | 1.51 |

### Aspects

In a first aspect, the invention provides a composition comprising:
a. water;
b. a cleaning additive chosen from cysteine; cystine; 2-aminothiophenol; 2-thiazoline-2-thiol; 1,3,4-thiadiazole-2-,5-dithiol; 1,3,4-thiadiazole-2-methyl-5-thiol; and ethyldithiocarbamate; and salts thereof;
c. a chelating agent chosen from monoethanolamine; ethanolamine; hydroxyethylidene diphosphonic acid; 2-amino-2-(hydroxymethyl)-1,3-propanediol; diglycolamine; diisopropanolamine; isopropanolamine; nitrilo tris-(methylenephosphonic acid); diethylene triamine pentamethylene phosphonic acid; phosphoric acid; and triethanolamine;
d. a reducing agent chosen from diethyl hydroxylamine, ascorbic acid, hypophosphorous acid and sulfurous acid;
e. a corrosion inhibitor chosen from dicyandiamide; guanylurea; and glycocyamine; and
f. a pH adjustor.

In a second aspect, the invention provides the composition of the first aspect, wherein the nucleophile is chosen from cysteine, cystine, and 1,3,4-thiadiazole-2-methyl-5-thiol.

In a third aspect, the invention provides the composition of the first or second aspect, wherein the chelating agent is chosen from monoethanolamine; 2-amino-2-(hydroxymethyl)-1,3-propanediol; triethanolamine; and hydroxyethylidene diphosphonic acid.

In a fourth aspect, the invention provides the composition of the first, second, or third aspect, wherein the reducing agent is chosen from diethylhydroxylamine; ascorbic acid; and hypophosphorous acid.

In a fifth aspect, the invention provides the composition of any one of the first through fourth aspects, wherein the corrosion inhibitor is chosen from dicyandiamide, guanylurea and glycocyamine.

In a sixth aspect, the invention provides the composition of any one of the first through the fifth aspects, wherein the pH adjustor is chosen from choline hydroxide; potassium hydroxide; tetraethylammonium hydroxide; and methyl tris (hydroxyethyl)ammonium hydroxide.

In a seventh aspect, the invention provides the composition of any one of the first through the sixth aspects, wherein the pH of the composition is greater than or equal to 8.

In an eighth aspect, the invention provides the composition of any one of the first through the seventh aspects, wherein d. is diethyl hydroxylamine, and e. is dicyandiamide.

In a ninth aspect, the invention provides the composition of the first aspect, comprising:
a. water,
b. monoethanolamine;
c. cysteine;
d. diethyl hydroxylamine;
e. dicyandiamide; and
f. a pH adjustor.

In a tenth aspect, the invention provides the composition of the ninth aspect, wherein the pH adjustor is choline.

In an eleventh aspect, the invention provides the composition of any one of the first through tenth aspects, further comprising one or more chelating agents chosen from 1-hydroxyethylidene-1,1-diphosphonic acid; 1,5,9-triazacyclododecane-N,N′,N″-tris(methylenephosphonic acid); 1,4,7,10-tetraazacyclododecane-N,N′,N″,N″′-tetrakis(methylenep-hosphonic acid); nitrilotris(methylene)triphosphonic acid, diethylenetriaminepentakis(methylenephosphonic acid), aminotri(methylenephosphonic acid), bis(hexamethylene)triamine pentamethylene phosphonic acid, 1,4,7-triazacyclononane-N,N′,N″-tris(methylenephosphonic acid, hydroxyethyldiphosphonate, nitrilotris(methylene)phosphonic acid; 2-phosphono-butane-1,2,3,4-tetracarboxylic, carboxyethyl phosphonic acid, aminoethyl phosphonic acid; glyphosate; ethylene diamine tetra(methylenephosphonic acid) phenylphosphonic acid, oxalic acid, succinic acid, maleic acid, malic acid, malonic acid, adipic acid, phthalic acid, citric acid, tricarballylic acid, dimethylolpropionic acid, trimethylolpropionic acid, tartaric acid, glucuronic acid, 2-carboxypyridine, 4,5-dihydroxy-1,3-benzenedisulfonic acid and salts thereof.

In a twelfth aspect, the invention provides the composition of any one of the first through the eleventh aspects, further comprising one or more water-miscible solvents.

In a thirteenth aspect, the invention provides the composition of the twelfth aspect, wherein the water-miscible solvent is chosen from triethylene glycol monobutyl ether, propylene glycol n-butyl ether, dimethyl sulfoxide and diethylene glycol monophenyl ether.

In a fourteenth aspect, the invention provides the composition of any one of the first through the thirteenth aspects, further comprising one or more surfactants.

In a fifteenth aspect, the invention provides the composition of any one of the first through fourteenth aspects, further comprising one or more water-dispersible or water-soluble polymers.

In a sixteenth aspect, the invention provides a method for removing residues on a microelectronic device substrate, the method comprising:
A. contacting the surface of the microelectronic device substrate with a composition comprising:
   a. water;
   b. a cleaning additive chosen from cysteine; cystine; 2-aminothiophenol, 2-thiazoline-2-thiol, 1,3,4-thiadiazole-2-,5-dithiol, 1,3,4-thiadiazole-2-methyl-5-thiol, ethyldithiocarbamate and salts thereof;
   c. a chelating agent chosen from monoethanolamine, ethanolamine, hydroxyethylidene diphosphonic acid, 2-amino-2-(hydroxymethyl)-1,3-propanediol, diglycolamine, diisopropanolamine, isopropanolamine, nitrilo tris-(methylenephosphonic acid), diethylene triamine pentamethylene phosphonic acid, phosphoric acid and triethanolamine;
   d. a compound chosen from diethyl hydroxylamine, ascorbic acid, hypophosphorous acid, and sulfurous acid;
   e. a corrosion inhibitor chosen from dicyandiamide; guanylurea; and glycocyamine; and
   f. a pH adjustor; and
B. at least partially removing the residues from the microelectronic device substrate.

In a seventeenth aspect, the invention provides the method of the sixteenth aspect, wherein the composition the cleaning additive is chosen from cysteine, cystine, and 1,3,4-thiadiazole-2-methyl-5-thiol.

In an eighteenth aspect, the invention provides the method of the sixteenth or seventeenth aspect, wherein the chelating agent is chosen from monoethanolamine, 2-amino-2-(hydroxymethyl)-1,3-propanediol, triethanolamine, and hydroxyethylidene diphosphonic acid.

In a nineteenth aspect, the invention provides the method of the sixteenth, seventeenth, or eighteenth aspect, wherein the reducing agent is chosen from diethylhydroxylamine, ascorbic acid, and hypophosphorous acid.

In a twentieth aspect, the invention provides the method of any one of the sixteenth through the nineteenth aspects, wherein the corrosion inhibitor is chosen from dicyandiamide, guanylurea, and glycocyamine.

In a twenty-first aspect, the invention provides the method of any one of the sixteenth through the twentieth aspects, wherein the pH adjustor is chosen from choline hydroxide, potassium hydroxide, tetraethylammonium hydroxide, and methyl tris (hydroxyethyl)ammonium hydroxide.

In a twenty-second aspect, the invention provides the method of the sixteenth aspect, wherein the composition comprises:
a. water,
b. monoethanolamine;
c. cysteine;
d. diethyl hydroxylamine;
e. dicyandiamide; and
f. a pH adjustor.

In a twenty-third aspect, the invention provides the method of the twenty-second aspect, wherein the pH adjustor is choline.

In a twenty-fourth aspect, the invention provides a kit, comprising in one or more containers, two or more of
a. a cleaning additive chosen from cysteine; cystine; 2-aminothiophenol; 2-thiazoline-2-thiol; 1,3,4-thiadiazole-2-,5-dithiol; 1,3,4-thiadiazole-2-methyl-5-thiol; and ethyldithiocarbamate; and salts thereof;
b. a chelating agent chosen from monoethanolamine, ethanolamine, hydroxyethylidene diphosphonic acid, 2-amino-2-(hydroxymethyl)-1,3-propanediol, diglycolamine, diisopropanolamine, isopropanolamine, nitrilo tris-(methylenephosphonic acid), diethylene triamine pentamethylene phosphonic acid, phosphoric acid and triethanolamine;
c. a reducing agent chosen from diethyl hydroxylamine, ascorbic acid, hypophosphorous acid and sulfurous acid;
d. a corrosion inhibitor chosen from dicyandiamide, guanylurea and glycocyamine; and
e. a pH adjustor.

Having thus described several illustrative embodiments of the present disclosure, those of skill in the art will readily appreciate that yet other embodiments may be made and used within the scope of the claims hereto attached. Numerous advantages of the disclosure covered by this document have been set forth in the foregoing description. It will be understood, however, that this disclosure is, in many respects, only illustrative. The disclosure's scope is, of course, defined in the language in which the appended claims are expressed.

What is claimed is:

1. A composition comprising:
a. water;
b. a cleaning additive chosen from cysteine, cystine, 2-aminothiophenol, 2-thiazoline-2-thiol, 1,3,4-thiadiazole-2-,5-dithiol, 1,3,4-thiadiazole-2-methyl-5-thiol, ethyldithiocarbamate, and salts thereof;
c. a chelating agent chosen from monoethanolamine, ethanolamine, hydroxyethylidene diphosphonic acid, 2-amino-2-(hydroxymethyl)-1,3-propanediol, diglycolamine; diisopropanolamine, isopropanolamine, nitrilo tris-(methylenephosphonic acid), diethylene triamine pentamethylene phosphonic acid, phosphoric acid, and triethanolamine;
d. a reducing agent chosen from diethyl hydroxylamine, ascorbic acid, hypophosphorous acid and sulfurous acid;
e. a corrosion inhibitor chosen from dicyandiamide, guanylurea and glycocyamine; and
f. a pH adjustor.

2. The composition of claim 1, wherein the nucleophile is chosen from cysteine, cystine, and 1,3,4-thiadiazole-2-methyl-5-thiol.

3. The composition of claim 1, wherein the chelating agent is chosen from monoethanolamine, 2-amino-2-(hydroxymethyl)-1,3-propanediol, triethanolamine and hydroxyethylidene diphosphonic acid.

4. The composition of claim 1, wherein the reducing agent is chosen from diethyl hydroxylamine, ascorbic acid and hypophosphorous acid.

5. The composition of claim 1, wherein the corrosion inhibitor is dicyandiamide.

6. The composition of claim 1, wherein the pH adjustor is chosen from choline hydroxide; potassium hydroxide; tetraethylammonium hydroxide; and methyl tris (hydroxyethyl)ammonium hydroxide.

7. The composition of claim 1, wherein the reducing agent is diethyl hydroxylamine, and the corrosion inhibitor is dicyandiamide.

8. The composition of claim 1, comprising:
a. water,
b. monoethanolamine;
c. cysteine;
d. diethyl hydroxylamine;
e. dicyandiamide; and
f. a pH adjustor.

9. The composition of claim 1, further comprising one or more additional complexing agents chosen from 1-hydroxyethylidene-1,1-diphosphonic acid, 1,5,9-triazacyclododecane-N,N′,N″-tris(methylenephosphonic acid), 1,4,7,10-tetraazacyclododecane-N,N′,N″,N″′-tetrakis(methylenep-hosphonic acid), nitrilotris(methylene)triphosphonic acid, diethylenetriaminepentakis(methylenephosphonic acid), aminotri(methylenephosphonic acid), bis(hexamethylene)triamine pentamethylene phosphonic acid, 1,4,7-triazacyclononane-N,N′,N″-tris(methylenephosphonic acid, hydroxyethyldiphosphonate, nitrilotris(methylene)phosphonic acid, 2-phosphono-butane-1,2,3,4-tetracarboxylic acid, carboxyethyl phosphonic acid, aminoethyl phosphonic acid, glyphosate; ethylene diamine tetra(methylenephosphonic acid) phenylphosphonic acid, oxalic acid, succinic acid, maleic acid, malic acid, malonic acid, adipic acid, phthalic acid, citric acid, tricarballylic acid, dimethylolpropionic acid, trimethylolpropionic acid, tartaric acid, glucuronic acid, 2-carboxypyridine, 4,5-dihydroxy-1,3-benzenedisulfonic acid and salts thereof.

10. The composition of claim 1, further comprising one or more water-miscible solvents.

11. The composition of claim 10, wherein the water-miscible solvent is chosen from triethylene glycol monobutyl ether, propylene glycol n-butyl ether, dimethyl sulfoxide and diethylene glycol monophenyl ether.

12. The composition of claim 1, further comprising one or more surfactants.

13. The composition of claim 1, further comprising one or more water-dispersible or water-soluble polymers.

14. A method for removing residues on a microelectronic device substrate, the method comprising:
A. contacting the surface of the microelectronic device substrate with a composition comprising:
a. water;
b. a cleaning additive chosen from cysteine, cystine, 2-aminothiophenol, 2-thiazoline-2-thiol, 1,3,4-thiadiazole-2-,5-dithiol, 1,3,4-thiadiazole-2-methyl-5-thiol, ethyldithiocarbamate and salts thereof;
c. a chelating agent chosen from monoethanolamine, ethanolamine, hydroxyethylidene diphosphonic acid, 2-amino-2-(hydroxymethyl)-1,3-propanediol, diglycolamine, diisopropanolamine, isopropanolamine, nitrilo tris-(methylenephosphonic acid), diethylene triamine pentamethylene phosphonic acid, phosphoric acid and triethanolamine;
d. a reducing agent chosen from diethyl hydroxylamine, ascorbic acid, hypophosphorous acid, and sulfurous acid;
e. a corrosion inhibitor chosen from dicyandiamide, guanylurea and glycocyamine; and
f. a pH adjustor; and
B. at least partially removing the residues from the microelectronic device substrate.

15. The method of claim 14, wherein the composition the cleaning additive is chosen from cysteine, cystine, and 1,3,4-thiadiazole-2-methyl-5-thiol.

16. The method of claim 14, wherein the chelating agent is chosen from monoethanolamine, 2-amino-2-(hydroxymethyl)-1,3-propanediol, triethanolamine, and hydroxyethylidene diphosphonic acid.

17. The method of claim 14, wherein the reducing agent is chosen from diethylhydroxylamine, ascorbic acid, and hypophosphorous acid.

18. The method of claim 14, wherein the corrosion inhibitor is dicyandiamide.

19. The method of claim 14, wherein the pH adjustor is chosen from choline hydroxide, potassium hydroxide, tetraethylammonium hydroxide, and methyl tris (hydroxyethyl)ammonium hydroxide.

20. The method of claim 14, wherein the composition comprises:
a. water,
b. monoethanolamine;
c. cysteine;
d. diethyl hydroxylamine;
e. dicyandiamide; and
f. a pH adjustor.
